(19) United States
(12) Patent Application Publication
(10) Pub. No.: US 2011/0053088 A1
(43) Pub. Date: Mar. 3, 2011

(54) ELECTRON BEAM LITHOGRAPHY METHOD AND METHOD FOR PRODUCING A MOLD

(75) Inventors: Toshihiro USA, Odawara-shi (JP); Satoshi CHAI, Odawara-shi (JP); Ikuo TAKANO, Odawara-shi (JP)

(73) Assignee: FUJIFILM CORPORATION, Tokyo (JP)

(21) Appl. No.: 12/868,215

(22) Filed: Aug. 25, 2010

(30) Foreign Application Priority Data
Aug. 25, 2009 (JP) 2009-193865

(51) Int. Cl. G03F 7/20

(52) U.S. Cl. 430/296

(57) ABSTRACT

Fine patterns to be formed on recording media such as DTM or BPM are drawn onto a mold original plate, on which resist is coated, by scanning an electron beam with an electron beam lithography apparatus. At this time, at least two types of patterns from among a group of: first patterns of protrusions and recesses constituted by media servo patterns and group patterns among data tracks; second patterns of protrusions and recesses constituted by annular positioning marks formed along the circumference of the mold as annular patterns and product identifying marks for tracing products; and third patterns of protrusions and recesses constituted by point like orientation marks used during transfer from the mold to the recording media are continuously drawn onto a single mold original plate within a single vacuum chamber by electron beam lithography.

### BACKGROUND OF THE INVENTION

1. Field of the Invention

The present invention is related to an electron beam lithography method, for drawing patterns by irradiating an electron beam to a resist provided onto an original plate for a mold, in order to form a fine pattern (pattern of protrusions and recesses) on a mold for producing recording media, such as discrete track media or bit pattern media. The present invention is also related to a method for producing a mold for discrete track media or bit pattern media, having a pattern of protrusions and recesses formed by the steps of the electron beam lithography method.

2. Description of the Related Art

Discrete track media (hereinafter, referred to simply as “DTM”) are recording media, in which adjacent data tracks are separated by group patterns (guard bands) constituted by grooves, to reduce magnetic interference among adjacent tracks, in response to demand for magnetic disk media having higher recording densities. Bit pattern media (hereinafter, referred to simply as “BPM”) are recording media, in which a magnetic material (single domain magnetic material) that constitutes a single domain is separated into data bits by arrangements of each dot element of a dot pattern, the data bits being physically isolated and arranged regularly to record one bit of data in each fine particle. A nano imprinting technique is employed to produce these recording media (refer to U.S. Patent Application Publication No. 20070164458, for example).

In the nano imprinting technique, a mold having a fine pattern of protrusions and recesses corresponding to a fine pattern of protrusions and recesses to be formed on the surface of a recording medium is produced. The mold is pressed against the resin material of a substrate, to transfer the fine pattern thereto.

The pattern of protrusions and recesses to be formed on the DTM or the BPM include servo patterns for servo tracking that cause heads to follow tracks, the data group patterns or the dot patterns, positioning marks for positioning the mold when the mold is pressed onto the substrate of the DTM or the BPM to transfer the pattern of protrusions and recesses thereto, and product identification marks (product tracing marks).

Examples of the positioning marks include annular positioning marks for matching the center positions of the DTM substrate or the BPM substrate with the center position of the mold, formed as an annular pattern along the circumference of the mold, and point like orientation marks for matching positions in the rotating direction when the pattern of the mold is transferred onto media.

The product identification marks are provided in order to enable identification of a mold which was utilized to produce DTM or BPM products. Such identification may be necessary to analyze and to deal with abnormalities, in cases that abnormalities occur at a production step after utilizing the mold, or in cases that abnormalities occur in products which are shipped out. A product number (numerals and the like) is an example of a product identification mark.

In cases that patterns of protrusions and recesses that correspond to the aforementioned servo patterns, the data group patterns or the dot patterns, the positioning marks, and the product identification marks are formed on the mold, it is necessary for the patterns to be formed on an original plate that constitutes the mold. Forming the patterns onto a resist, which is coated on the original plate of the mold, by photolithography, laser beam lithography, and electron beam lithography are widely known techniques for forming these patterns. There are appropriate pattern formation methods corresponding to degrees of fineness of patterns (pattern size), such as the thickness of the lines of the patterns and the sizes of pixels.

For example, in U.S. Patent Application Publication No. 20070164458, it is described that two or more concentric positioning marks are formed on a mold for nano imprinting by a photolithography process and a dry etching technique. Then, fine patterns of protrusions and recesses, such as servo patterns, are formed by electron beam lithography. The aforementioned positioning marks are utilized as marks to position the mold with respect to a substrate when the mold is pressed against the substrate.

In the case that the patterns of protrusions and recesses are formed on a single mold by different methods, such as photolithography and electron beam lithography, it becomes necessary to hold the original plate for the mold at reference positions of different apparatuses that perform each pattern formation method. This causes a problem that positional shifting occurs between the patterns formed by each of the different apparatuses.

That is, there is an appropriate pattern formation method corresponding to the drawing properties of patterns and marks having different pattern sizes. If patterns are formed with formation methods suited thereto, efficient and accurate pattern formation is enabled. However, because the original plate for the mold is moved from one apparatus to another, it is difficult to match the mechanical holding positions in each apparatus, which is a hindrance to improving accuracy.

Particularly, servo patterns, data group patterns, and dot patterns are fine patterns, whereas annular positioning marks are patterns having low fineness. Further, product identification marks are formed at sizes that enable visual recognition. Positional shifts are present in molds, in which drawing of servo patterns and data group patterns or dot patterns, and formation of positioning marks are performed by different processes.

Accordingly, there is a problem that when patterns of protrusions and recesses are transferred onto DTM substrates or BPM substrates using these molds, servo patterns cannot be formed at accurate positions on DTM or BPM substrates due to positional shifts between the positioning marks and the servo patterns formed on the molds, even if the positioning marks are employed to perform accurate positioning of the molds with respect to the substrates.

### SUMMARY OF THE INVENTION

The present invention has been developed in view of the foregoing circumstances. It is an object of the present invention to provide an electron beam lithography method for producing molds for discrete track media or bit pattern media, which is capable of securing drawing position accuracy of patterns of various types having different pattern sizes. It is another object of the present invention to provide a mold produced by the electron beam lithography method.

An electron beam lithography method of the present invention comprises the steps of:

coating an original plate for a mold with resist;

placing the original plate on a rotating stage; and

scanning an electron beam with an electron beam lithography apparatus onto the original plate while the rotating stage is rotating, to draw a fine pattern to be formed on recording media, and is characterized by:

the fine pattern including first patterns of protrusions and recesses, which are one of group patterns that separate servo patterns for the recording media and adjacent data tracks in a groove like manner and dot patterns for separating data bits, second patterns of protrusions and recesses, which are one of annular positioning marks formed along the circumference of the mold as annular patterns and product identifying marks for tracing products, and third patterns of protrusions and recesses, which are point like orientation marks used during transfer from the mold to the recording media; and

at least two types of the first patterns of protrusions and recesses, the second patterns of protrusions and recesses, and the third patterns of protrusions and recesses being continuously drawn onto a single original plate within a single vacuum chamber by electron beam lithography.

In the electron beam lithography method of the present invention, it is preferable for:

the electron beam lithography apparatus to have a function of varying the beam irradiation dosage and the beam diameter of the emitted electron beam; and

lithography to be performed such that the beam irradiation dosage and the beam diameter are set to be greater while drawing the second patterns of protrusions and recesses than those while drawing the first patterns of protrusions and recesses.

In addition, in the electron beam lithography method of the present invention, it is preferable for:

the electron beam lithography apparatus to have a function of varying the beam irradiation dosage and the beam diameter of the emitted electron beam; and

lithography to be performed such that the beam irradiation dosage and the beam diameter while drawing the third patterns of protrusions and recesses are the same as those while drawing the first patterns of protrusions and recesses.

A method for producing a mold having a pattern of protrusions and recesses corresponding to a fine pattern of the present invention comprises the steps of:

coating a original plate for the mold with resist;

drawing the fine pattern to be formed on recording media by the electron beam lithography method of the present invention; and

exposing the resist.

In the electron beam lithography method of the present invention, at least two types of the first patterns of protrusions and recesses, which are one of group patterns among adjacent data tracks and dot patterns, second patterns of protrusions and recesses, which are one of annular positioning marks and product identifying marks for tracing products, and third patterns of protrusions and recesses, which are point like orientation marks, are continuously drawn onto a single original plate within a single vacuum chamber by electron beam lithography, when the fine pattern to be formed on DTM or BPM is drawn on the original plate of the mold, on which resist is coated, by scanning the electron beam. Thereby, positional shifting of the central positions in cases that these patterns of protrusions and recesses are drawn in different steps, in which the holding manner of the original plate is changed, can be suppressed. Therefore, each of the patterns of protrusions and recesses can be drawn accurately. In addition, when the mold is employed to transfer the patterns of protrusions and recesses to DTM substrates or BPM substrates, the positioning marks improve the positioning accuracy with respect to the substrates, thereby forming the servo patterns and the group patterns or dot patterns at accurate positions of the DIM substrates or BPM substrates, enabling obtainment of superior properties.

In the lithography method of the present invention, the electron beam lithography apparatus may have a function of varying the beam irradiation dosage and the beam diameter of the emitted electron beam; and lithography may be performed such that the beam irradiation dosage and the beam diameter are set to be greater while drawing the second patterns of protrusions and recesses than those while drawing the first patterns of protrusions and recesses. In this case, the accuracy of the central position of drawing during lithography of the second patterns of protrusions and recesses, which are of a large pattern size, can be secured, while the time required for lithography can be reduced, by an improvement in drawing speed.

In addition, in the lithography method of the present application, the electron beam lithography apparatus may have a function of varying the beam irradiation dosage and the beam diameter of the emitted electron beam; and lithography may be performed such that the beam irradiation dosage and the beam diameter while drawing the third patterns of protrusions and recesses are the same as those while drawing the first patterns of protrusions and recesses. In this case, the irradiation properties of the electron beam are not changed between lithography of the first and third patterns of protrusions and recesses, which are of equivalent pattern sizes. Therefore, phase shifts due to changes in the beam properties will not occur, and the first and third patterns of protrusions and recesses can be formed with accurate positional relationships.

Further, the method for producing a mold of the present invention comprises the steps of: coating a original plate for the mold with resist; drawing a fine pattern to be formed on DTM or BPM by the electron beam lithography method of the present invention; and exposing the resist. Therefore, production of a mold having a highly accurate pattern of protrusions and recesses is facilitated. By utilizing the mold of the present invention to produce DTM or BPM, the pattern of protrusions and recesses on the surface of the mold can be transferred, thereby facilitating production of DTM or BPM having superior properties.

### BRIEF DESCRIPTION OF THE DRAWINGS

FIG. 1 is a plan view of the entirety of a fine pattern for DTM which is drawn on to an original plate for a mold by an electron beam lithography method of the present invention.

FIG. 2 is a magnified view of a portion of the fine pattern.

FIG. 3 is a diagram that illustrates the schematic configuration of an electron beam lithography apparatus for executing the electron beam lithography method of the present invention.

FIG. 4 is a sectional view that illustrates a step of transferring a fine pattern, drawn on a mold of the present invention by the electron beam lithography method of the present invention, onto a magnetic disc medium.

### DESCRIPTION OF THE PREFERRED EMBODIMENTS

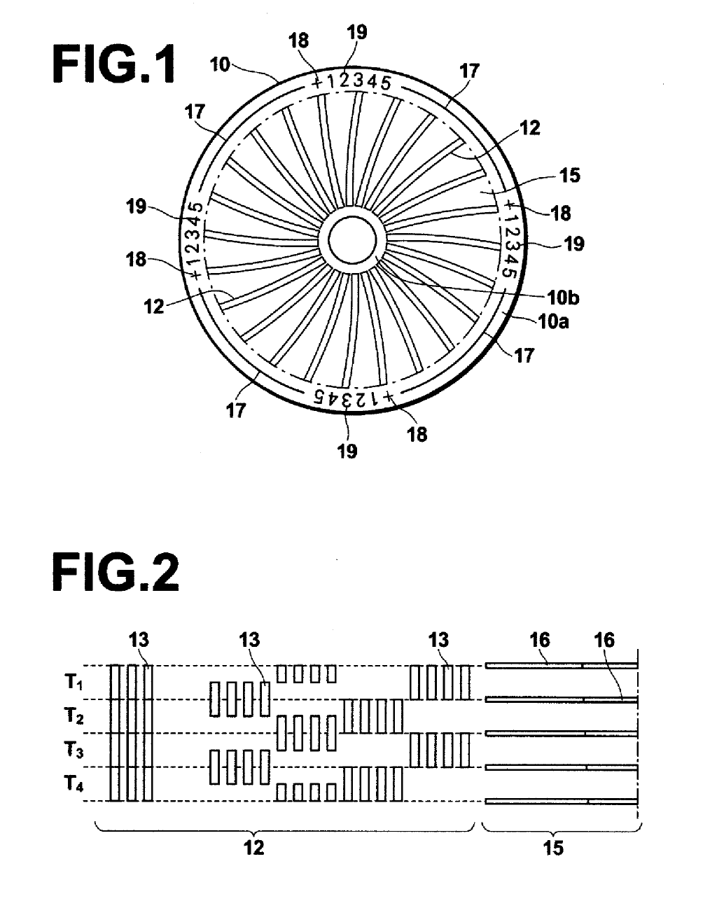

Hereinafter, an embodiment of the present invention will be described in detail with reference to the attached drawings. FIG. 1 and FIG. 2 illustrate a DTM mold as an embodiment of the present invention.

As illustrated in FIG. 1 and FIG. 2, a fine pattern of protrusions and recesses for DTM is constituted by servo patterns 12, which are formed in servo regions, and group patterns 15, which are formed in data regions. The fine pattern is formed within an annular region of a mold original plate 10, excluding the outer peripheral portion 10b and a central portion 10b.

As illustrated in FIG. 1, the servo patterns 12 are formed in thin regions that extend substantially radially outward at equidistant intervals along concentric tracks from the center of the mold original plate 10. The servo patterns 12 of this example are formed as curved lines that radiate outward continuously in the radial direction. As shown in the magnified view of FIG. 2 that illustrates a portion of the fine pattern, fine rectangular servo elements 13 that correspond to preamble, address, and burst signals are formed on concentric tracks T1 through T4. Each servo element has a width of a single track, and a length in the track direction greater than the irradiation beam diameter of an electron beam. A portion of the servo elements corresponding to burst signals are provided shifted half a track so as to straddle adjacent tracks.

Meanwhile, the group patterns 15 are formed concentrically within guard bands among data tracks so as to separate the adjacent tracks T1 through T4 with grooves. The group patterns 15 are constituted by a plurality of group elements 16. which are aligned and separated at predetermined angles.

In the DTM as a whole, portions corresponding to the servo elements 13, the group elements 16, annular positioning marks 17 to be described later, point like orientation marks 18, and product identification marks 19 are formed as recesses, and the other portions are formed as lands constituted by a magnetic layer.

As illustrated in FIG. 1, positioning marks for performing positioning of the mold with respect to DTM substrates during pressing and transfer are provided as other patterns of protrusions and recesses. The positioning marks include the annular positioning marks 17, which are formed along the circumference in the outer peripheral portion 10a (non user region) of the mold original plate 10, and a plurality of point like orientation marks 18 for performing phase positioning of the DIM substrates and the mold, constituted by a plurality of +marks formed at portions (four locations) of the annular positioning marks 17.

Product identification marks 19 (product tracing marks) are provided as still another type of fine pattern. The product identification marks 19 are provided as the product number (numerals and the like) of the mold, in the vicinity of the point like orientation marks 18 formed at four locations along the annular positioning marks 17 in the outer peripheral portion 10a of the mold original plate 10.

The shapes (pattern sizes) of each type of pattern of protrusions and recesses differ in the following manner, and are grouped with respect to the drawing order thereof. The pattern size of first patterns of protrusions and recesses that include the servo elements 13 of the servo patterns 12 and the group elements 16 of the group patterns 15 is particularly fine, with widths within a range from 20 nm to 100 nm. Meanwhile, the pattern size of second patterns of protrusions and recesses that include the annular positioning marks 17 is comparatively large, with the line width of the annular marks being approximately 1.5 m. The pattern size of third patterns of protrusions and recesses that include the point like orientation marks 18 is fine, with the line width of the +symbols being approximately 200 nm. Further, the pattern size of the second patterns of protrusions and recesses that also include the product identification marks 19 is even greater, with the line width of the numerals (product number) being approximately 50 μm, in order to enable visual recognition.

That is, pattern sizes of the first patterns of protrusions and recesses (the servo patterns 12 and the group patterns 15) and the third patterns of protrusions and recesses (the point like orientation marks 18) are fine, while the pattern size of the second patterns of protrusions and recesses (the annular positioning marks 17 and the product identification marks 19) is at least 10 times greater than those of the first and third patterns.

The annular positioning marks 17 are provided to match the positions of the rotational centers of the DTM substrates and the mold original plate 10 in the X-Y directions. In the example illustrated in FIG. 1, annular patterns are formed along the circumference in the outer peripheral portion 10b. Alternatively, annular patterns may be formed in the central portion 10b, which is also a non user region. As a further alternative, the annular positioning marks 17 may be formed by a plurality of concentric rings.

The point like orientation marks 18 are provided to perform phase positioning of the DTM substrates and the mold original plate 10 in the rotating direction, and are constituted by at least one point discrete from the rotational center. In the example illustrated in FIG. 1, the cruciform+symbols are formed at four locations along the circumference. Alternatively, the point like orientation marks may be formed along at least one normal line that extends radially from the center of the mold original plate 10. As a further alternative, the point like orientation marks may be formed in the central portion 10b, which is also a non user region.

Although not illustrated in the drawings, fine patterns of protrusions and recesses for BPM are constituted by servo patterns which are formed within servo regions, dot patterns (dot elements) for separating data bits, formed in data regions, positioning marks similar to those of the DTM (annular positioning marks and point like orientation marks), and product identification marks. With respect to the pattern size of each type of pattern of protrusions and recesses, the servo patterns and the dot patterns (having widths within a range from 10 nm to 25 nm, for example), correspond to the aforementioned first patterns of protrusions and recesses, the annular positioning marks and the product identification marks correspond to the second patterns of protrusions and recesses, and the point like orientation marks correspond to the third patterns of protrusions and recesses. The patterns of protrusions and recesses are formed by an electron beam lithography method in the same manner as that for DTM, to be described later.

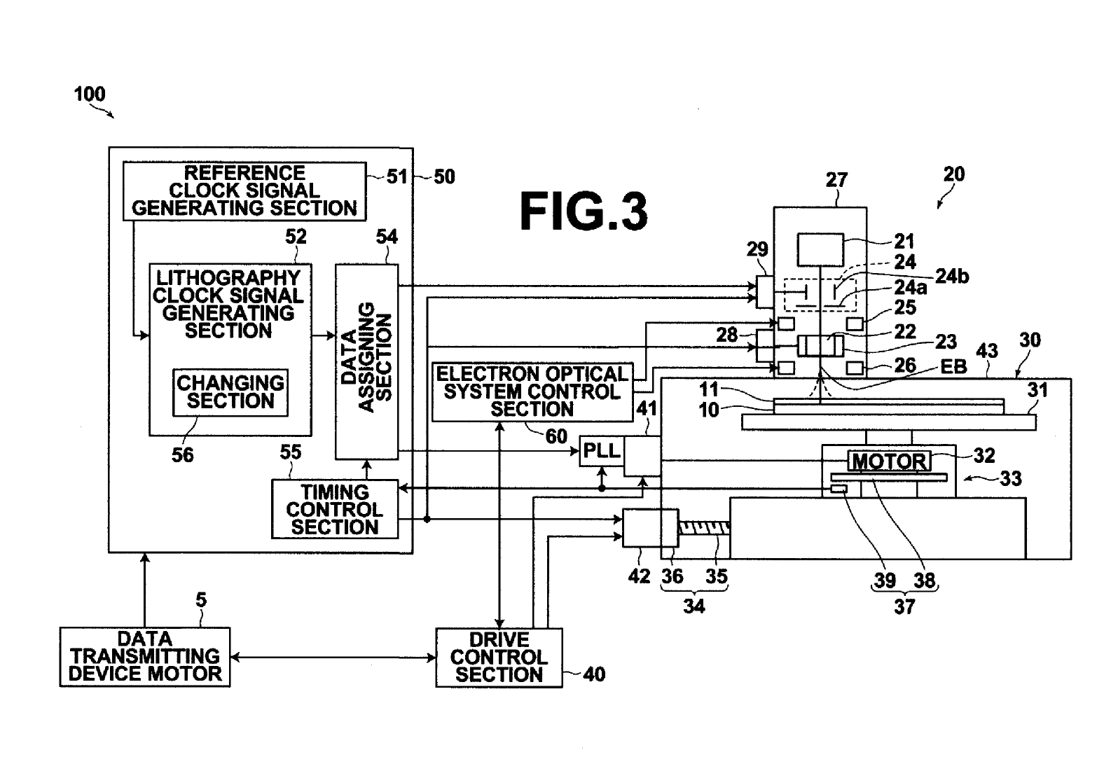

The first through third patterns of protrusions and recesses are formed employing an electron beam lithography apparatus 100 such as that illustrated in FIG. 3. The surface of the mold original plate 10 is coated with resist 11, and the mold original plate 10 is placed on a rotating stage 31. An electron beam EB is irradiated, deflected, and scanned within a vacuum chamber while rotating the rotating stage 31, to expose and draw the first through third patterns sequentially.

For example, the servo elements 13 and the group elements 16 of the servo patterns 12 and the group patterns 15, which belong to the first patterns of protrusions and recesses, are formed by sequentially scanning the electron beam in the shapes of the elements 13 and 16 one track at a time from the inner tracks to the outer tracks, or in the opposite direction while rotating the mold original plate 10, and exposing the resist 11.

At this time, the order in which the first through third patterns of protrusions and recesses are drawn is as follows. First, the second patterns of protrusions and recesses (the annular positioning marks 17 and the product identification marks 19) having large pattern sizes are drawn. Next, the first patterns of protrusions and recesses (the servo patterns 12 and the group patterns 15) having small pattern sizes are drawn. Thereafter, the third patterns of protrusions and recesses (the point like orientation marks 18) are drawn. When the pattern size is changed, the beam irradiation properties and the speed of relative movement are also changed, as will be described later.

By lithography of the first through third patterns of protrusions and recesses being executed without changing the position in which the mold original plate 10 is held as described above, shifting of the central position of the annular positioning marks 17, the product identification marks 19, the servo elements 13, the group elements 16, and the point like orientation marks 18 does not occur, because the mechanical holding state of the mold original plate 10 is unchanged. Therefore, the patterns can be formed such that they have accurate positional relationships with respect to each other.

### <Electron Beam Lithography Apparatus>

An embodiment of an electron beam lithography apparatus for executing the electron beam lithography method of the present invention described above will be described. FIG. 3 is a diagram that illustrates the schematic structure of the electron beam lithography apparatus 100.

The electron beam lithography apparatus 100 is equipped with: an electron beam irradiating section 20, for irradiating an electron beam onto original plates; a drive section 30 for rotating and linearly moving the original plates; a drive control section 40, for exerting mechanical drive control on the drive section 30; a formatter 50, for generating lithography clock signals and for outputting operational timing signals for the electron beam irradiating section 20 and the drive section 30; an electron optical system control section 60, for exerting electron optical control on the electron beam emitted by the electron beam irradiating section 20; and a data transmitting device 5, for transmitting design data related to patterns to be drawn to the formatter 50. Data is exchanged among the data transmitting device 5, the drive control section 40 and the electron optical system control section 60.

The electron beam irradiating section 20 is provided within a lens tube 27. The electron beam irradiating section 20 is equipped with: an electron gun 21, for emitting the electron beam EB; deflecting means 22 and 23, for deflecting the electron beam EB in a radial direction Y and a circumferential direction X, and for reciprocally oscillating the electron beam EB in the circumferential direction X at a predetermined amplitude; and an aperture 24b and a deflector 24b that function as a blanking means 24 for controlling the irradiation of the electron beam EB ON and OFF. A condensing lens 25 (electromagnetic lens) that varies the beam irradiation dosage by diaphragm adjustments is provided above the deflecting means 22 and 23. An objective lens 26 (electromagnetic lens) that varies the beam diameter of the electron beam EB is provided beneath the deflecting means 22 and 23.

By the construction described above, the electron beam EB is emitted from the electron gun 21, and the beam irradiation dosage and the beam diameter thereof is adjusted by the condensing lens 25. The electron beam EB is then irradiated onto/shielded from and deflected to scan the mold original plate 10, which is coated with the resist 11, in the XY directions by the deflecting means 22 and 23. During the scanning operation, the beam diameter of the electron beam EB is adjusted by the objective lens 26.

The electron beam irradiating section 20 and the drive section 30 to be described later are provided within a vacuum chamber, the interior of which is depressurized. The electron lithography apparatus 100 is configured such that the electron beam EB is irradiated onto the mold original plate 10 placed within the vacuum chamber, to perform pattern lithography.

The aperture 24a of the blanking means is equipped with a transparent aperture through which the electron beam EB passes through at its center. The deflector 24b allows the electron beam EB to pass through the transparent aperture of the aperture 24b without deflecting the electron beam EB when an ON signal is input. On the other hand, when an OFF signal is input, the deflector 24b deflects the electron beam EB such that the electron beam does not pass through the transparent aperture of the aperture 24, and cuts the electron beam EB off at the aperture 24a such that it is not irradiated.

The drive section 30 is provided within a housing 43 having the lens tube 27 placed on the upper surface thereof. The drive section 30 is equipped with: a rotating stage unit 33 constituted by the rotating stage 31 for supporting original plates, and a spindle motor 32 having a motor shaft that matches the central axis of the stage 31; and a linear movement means 34, for moving the rotating stage unit 33 in a radial direction of the rotating stage 31. The linear movement means 34 is equipped with: a rod 35 having fine threads, which are in threaded engagement with a portion of the rotating stage unit 33; and a pulse motor 36, for driving the rod 35 to rotate in two rotational directions. An encoder 37 that outputs encoder signals corresponding to the rotational angle of the rotating stage 31 is provided in the rotating stage unit 33. The encoder 37 is equipped with: a rotating plate 38 having a plurality of radial slits therein, mounted on the motor shaft of the spindle motor 32; and an optical element 39 that optically reads the slits and outputs the encoder signals.

The drive control section outputs drive control signals to a driver 41 for the spindle motor 32 and to a driver 41 for the pulse motor 36 of the drive section 30, to control the driving thereof.

The formatter 50 is equipped with: a reference clock signal generating section 51 that generates invariable reference clock signals; a lithography clock signal generating section 52 that generates lithography clock signals; a data assigning section 54 that outputs data signals based on the lithography clock signals to a PLL circuit, which is connected to a deflecting amplifier for the deflecting means 22 and 23, a blanking amplifier 29 for the deflector 24b, and a driver 41 of the spindle motor 32; and a timing control section 55 that controls operational timings (data assignment timings) based on signals input from the encoder 37.

The lithography clock signal generating section 52 is equipped with a changing section that changes the frequency of the lithography clock signals according to the radial position of original plates. The number of lithography clock signals for drawing a single elements is set to be the same at the inner and outer peripheries of the original plates.

The data transmitting device 5 stores lithography design data (data that represent lithography patterns and lithography timings) of fine patterns constituted by the aforementioned first through third patterns of protrusions and recesses, such as hard disk patterns. The data transmitting device 5 transmits lithography design data signals to the drive control section 40, the formatter 50, the electron optical system control section 60.

The electron optical system control section 60 outputs control signals to the condensing lens 25 and the objective lens 26, which are electromagnetic lenses in the electron beam irradiating section 20, to control the electron optical properties of these electromagnetic lenses.

In the electron beam lithography apparatus 100, the data transmitting device 5 outputs the lithography design data signals to the formatter 50. The formatter 50 assigns the lithography design data as control signals to control ON/OFF operations of the blanking means 24, to control X-Y deflecting operations of the electron beam EB by the deflecting means 22 and 23, to control the rotational speed of the rotating stage 31 and the like, and assigns the control signals to the respective amplifiers 28 and 29 and the drivers 41 and 42. The control signals are synchronized with encoder signals which are output by the encoder 37, and output at predetermined timings. The blanking means 24, the deflecting means 22 and 23, the spindle motor 36, and the pulse motor 36 are driven based on the signals output from the formatter 50, to draw desired fine patterns on the entirety of the surfaces of original plates.

The lithography design data signals are output from the data transmitting device 5 also to the electron optical system control section 60. Control signals (operating current values) for controlling the condensing lens 25 and the objective lens 26 are changed according to the type of pattern to be drawn from among the first through third patterns of protrusions and recesses, to adjust the beam irradiation dosage and the beam diameter of the electron beam EB. Thereby, lithography accuracy and lithography speed suited for the type of pattern are set. At the same time, the rotational speed controlled by the spindle motor 32 and the lithography feed speed in the radial direction controlled by the deflecting means 23 and the pulse motor 36 are changed.

Next, lithography to draw a pattern of protrusions and recesses by the electron beam lithography apparatus 100 of the present embodiment will be described in detail. First, a mold original plate 10, which is coated with resist 11, is set on the rotating stage 31 within the housing 43, and the interior of the housing 43 is depressurized to a predetermined degree.

Next, the electron beam irradiating section 20 emits the electron beam EB, which is deflected and scanned, to draw the first through third patterns of protrusions and recesses 12, 15, and 17 through 19 in the order described previously. That is, in the present embodiment, first, the second patterns of protrusions and recesses that include the annular positioning marks 17 and the product identification marks 19 are drawn. Next, the first patterns of protrusions and recesses that include the media servo patterns 12 and the group patterns 15 are drawn. Thereafter, the third patterns of protrusions and recesses that include the point like orientation marks 18 are drawn.

The second patterns of protrusions and recesses that include annular positioning marks 17 and the product identification marks 19, which are drawn first, are of a large pattern size. In this case, the signal output to the condensing lens 25 of the electron beam irradiating section 20 that adjusts the aperture of the electron beam EB is set to a large current value (84 nA, for example), such that the irradiation dosage is increased. At the same time, the signal output to the objective lens 26 that changes the beam diameter of the electron beam EB is set such that a large beam diameter (40 nm, for example) is obtained. In addition, the amount of lithography feed per pitch is set to be high (35 nm, for example), and the rotational speed of the rotating stage 31 is set high (400 mm/sec, for example). Thereby, the second patterns of protrusions and recesses 17 and 19 are drawn quickly with a large beam diameter and high relative speed.

The first patterns of protrusions and recesses that include the media servo patterns 12 and the group patterns 15 to be drawn next are of a small pattern size. In this case, the signal output to the condensing lens 25 of the electron beam irradiating section 20 that adjusts the aperture of the electron beam EB is set to a small current value (10.5 nA, for example), such that the irradiation dosage is decreased. At the same time, the signal output to the objective lens 26 that changes the beam diameter of the electron beam EB is set such that a small beam diameter (20 nm, for example) is obtained. In addition, the amount of lithography feed per pitch is set to be low (18 nm, for example), and the rotational speed of the rotating stage 31 is set low (100 mm/sec, for example). Thereby, the first patterns of protrusions and recesses 12 and 15 are drawn accurately as fine shapes with a small beam diameter and low relative speed.

The third patterns of protrusions and recesses that include the point like orientation marks 18 to be drawn thereafter are of a small pattern size. In this case, the signal output to the condensing lens 25 of the electron beam irradiating section 20 that adjusts the aperture of the electron beam EB is set to a small current value (10.5 nA, for example), such that the irradiation dosage is decreased. At the same time, the signal output to the objective lens 26 that changes the beam diameter of the electron beam EB is set such that a small beam diameter (20 nm, for example) is obtained. In addition, the amount of lithography feed per pitch is set to be low (18 nm, for example), and the rotational speed of the rotating stage 31 is set low (100 mm/sec, for example). Thereby, the third patterns of protrusions and recesses 18 are drawn accurately as fine shapes with a small beam diameter and low relative speed.

In the embodiment described above, the second patterns of protrusions and recesses having the large pattern size are drawn before the first and third patterns of protrusions and recesses having the small pattern size. Alternatively, the first and third patterns of protrusions and recesses having the small pattern size may be drawn before the second patterns of protrusions and recesses having the large pattern size. In addition, the order in which the first and third patterns of protrusions and recesses having the small pattern size are drawn is interchangeable.

Note that in the case that the product identification marks 19 of the second patterns of protrusions and recesses are formed merely to be visually recognizable, they may be formed as patterns in a different step by a different method.

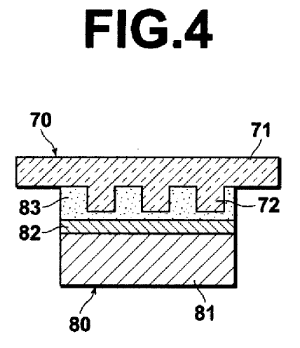

Next, FIG. 4 is a sectional view that illustrates a step of transferring a fine pattern of protrusions and recesses, drawn on an imprinting mold 70 by the electron beam lithography method described above, onto a recording medium (DTM or BPM).

The imprinting mold 70 is constituted by: a mold original plate 71 formed by a light transmissive material; and resist 11 (not shown) coated on the surface of the mold original plate 71. Servo patterns 12, group patterns 15, annular positioning marks 17, point like orientation marks 18, and product identification marks 19 for DTM or BPM are drawn on the resist. Thereafter, a developing process is administered, to form a resist pattern of protrusions and recesses on the mold original plate 71. The mold original plate 71 is etched using the patterned resist as a mask, ten the resist is removed, to obtain the imprinting mold 70, which has a fine pattern of protrusions and recesses 72 formed on the surface thereof.

The imprinting mold 70 is employed to produce a DTM or BPM recording medium 80 by the imprinting method. The recording medium 80 is equipped with a substrate 81, a magnetic layer 82, and a resin resist layer 83 for forming a mask layer on the magnetic layer 82. The fine pattern of protrusions and recesses 72 of the imprinting mold 70 is pressed against the resin resist layer 83, then ultraviolet rays are irradiated to cure the resin resist layer 83, to transfer the shapes of the protrusions and recesses of the fine pattern 72. Thereafter, the magnetic layer 82 is etched based on the shapes of the protrusions and recesses of the resin resist layer 83, to produce the recording medium 80 which has the magnetic layer 82 with a fine pattern of protrusions and recesses.

What is claimed is:

1. An electron beam lithography method, comprising the steps of:
coating an original plate for a mold with resist;
placing the original plate on a rotating stage; and
scanning an electron beam with an electron beam lithography apparatus onto the original plate while the rotating stage is rotating, to draw a fine pattern to be formed on recording media,
the fine pattern including first patterns of protrusions and recesses, which are one of group patterns that separate servo patterns for the recording media and adjacent data tracks in a groove like manner and dot patterns for separating data bits, second patterns of protrusions and recesses, which are one of annular positioning marks formed along the circumference of the mold as annular patterns and product identifying marks for tracing products, and third patterns of protrusions and recesses, which are point like orientation marks used during transfer from the mold to the recording media; and
at least two types of the first patterns of protrusions and recesses, the second patterns of protrusions and recesses, and the third patterns of protrusions and recesses being continuously drawn onto a single original plate within a single vacuum chamber by electron beam lithography.

2. An electron beam lithography method as defined in claim 1, wherein:
the electron beam lithography apparatus has a function of varying the beam irradiation dosage and the beam diameter of the emitted electron beam; and
lithography is performed such that the beam irradiation dosage and the beam diameter are set to be greater while drawing the second patterns of protrusions and recesses than those while drawing the first patterns of protrusions and recesses.

3. An electron beam lithography method as defined in claim 1, wherein:
the electron beam lithography apparatus has a function of varying the beam irradiation dosage and the beam diameter of the emitted electron beam; and
lithography is performed such that the beam irradiation dosage and the beam diameter while drawing the third patterns of protrusions and recesses are the same as those while drawing the first patterns of protrusions and recesses.

4. A method for producing a mold, having a pattern of protrusions and recesses corresponding to a fine pattern, comprising the steps of:
coating a original plate for the mold with resist;
drawing the fine pattern to be formed on recording media by an electron beam lithography method according to claim 1; and
exposing the resist.
